(19) United States
(12) Patent Application Publication
(10) Pub. No.: US 2006/0138668 A1
(43) Pub. Date: Jun. 29, 2006

(54) Passivation structure for semiconductor devices

(76) Inventors: Hung-Wen Su, Jhubei City (TW); Chien-Hsueh Shih, Taipei (TW); Minghsing Tsai, Chu-Pei City (TW); Shau-Lin Shue, Hsinchu (TW); Chen-Hua Yu, Hsin-Chu (TW)

Correspondence Address: SLATER & MATSIL, L.L.P., 17950 PRESTON ROAD, SUITE 1000, DALLAS, TX, 75252, US

(21) Appl. No.: 11/023,296

(22) Filed: Dec. 27, 2004

(51) Int. Cl. H01L 23/06

(52) U.S. Cl. 257/762

(57) ABSTRACT

A system and method for providing a passivation structure for semiconductor devices is provided. In an embodiment, the passivation structure comprises a first barrier layer and a second barrier layer, wherein the second barrier layer may comprise a material, such as cobalt and/or nickel, that is less pure than the first barrier layer. In another embodiment, a single gradient barrier layer is formed. In this embodiment the single gradient barrier layer exhibits a greater pure conductive material, such as cobalt and/or nickel, nearer the conductive line than near the surface.

### TECHNICAL FIELD

The present invention relates generally to semiconductors, and more particularly, to a cap layer over a conductive layer in a semiconductor device.

### BACKGROUND

Generally, integrated circuits (ICs) comprise electronic components, such as transistors, capacitors, or the like, formed on a substrate. One or more metal layers are then formed over the electronic components to provide connections between the electronic components and to provide connections to external devices. The metal layers typically comprise an inter-layer dielectric (ILD) layer in which vias and interconnects are formed, usually with a single- or dual-damascene process.

The trend in the semiconductor industry is towards the miniaturization or scaling of integrated circuits, in order to provide smaller ICs and improve performance, such as increased speed and decreased power consumption. While aluminum and aluminum alloys were most frequently used in the past for the material of conductive lines in integrated circuits, the current trend is to use copper for a conductive material because copper has better electrical characteristics than aluminum, such as decreased resistance, higher conductivity, and a higher melting point.

The change in the conductive line material and insulating materials of semiconductor devices has introduced new challenges in the manufacturing process. For example, copper oxidizes easily and has a tendency to diffuse into adjacent insulating materials, particularly when a low-K material or other porous insulator is used for the ILD layer. To reduce these effects, attempts have been made to form a cap layer comprising a single layer of CoWP over the copper material. While the CoWP cap layer helps reduce the oxidation and diffusion of the copper into the surrounding ILD layer, the CoWP cap layer does not contain the best adhesion qualities to the underlying copper material. As a result, voids may form between the cap layer and the copper material.

Accordingly, there is a need for a cap layer that eliminates or reduces surface migration and diffusion of the conductive material into adjacent insulating materials while providing good adhesion qualities to the conductive material.

### SUMMARY OF THE INVENTION

These and other problems are generally solved or circumvented, and technical advantages are generally achieved, by preferred embodiments of the present invention which provides a cap layer over a conductive material in a semiconductor device.

In accordance with an embodiment of the present invention, a method for forming an interconnect is provided. The method comprises providing a wafer having a conductive layer formed in a trench; forming a first cap layer over the conductive layer; and forming a second cap layer over the first cap layer, the composition of the first cap layer being different than the composition of the second cap layer.

In accordance with another embodiment of the present invention, a method for forming an interconnect is provided. The method comprises providing a wafer having a conductive layer formed in a trench; and forming a gradient cap layer over the conductive layer, wherein the gradient cap layer has a higher concentration of a first element near the conductive layer.

In accordance with still another embodiment of the present invention, an integrated circuit is provided. The integrated circuit comprises a conductive layer in a trench of a first dielectric layer; a first cap layer on the conductive layer; and a second cap layer on the first cap layer.

In accordance with yet another embodiment of the present invention, an integrated circuit is provided. The integrated circuit comprises a conductive layer in a trench of a first dielectric layer; and a gradient cap layer on the conductive layer.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1-4 are cross-section views of a wafer during various steps of an embodiment of the present invention;

FIGS. 5-6 are cross-section views of a wafer during various steps of an embodiment of the present invention; and

FIG. 7 is a cross-section view of a wafer illustrating an interconnection in accordance with an embodiment of the present invention.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to embodiments in a specific context, namely forming copper interconnects in an intermetal dielectric layer. The invention may also be applied, however, to other designs in which it is desirable to limit contamination between materials or to increase adhesive qualities of successive layers.

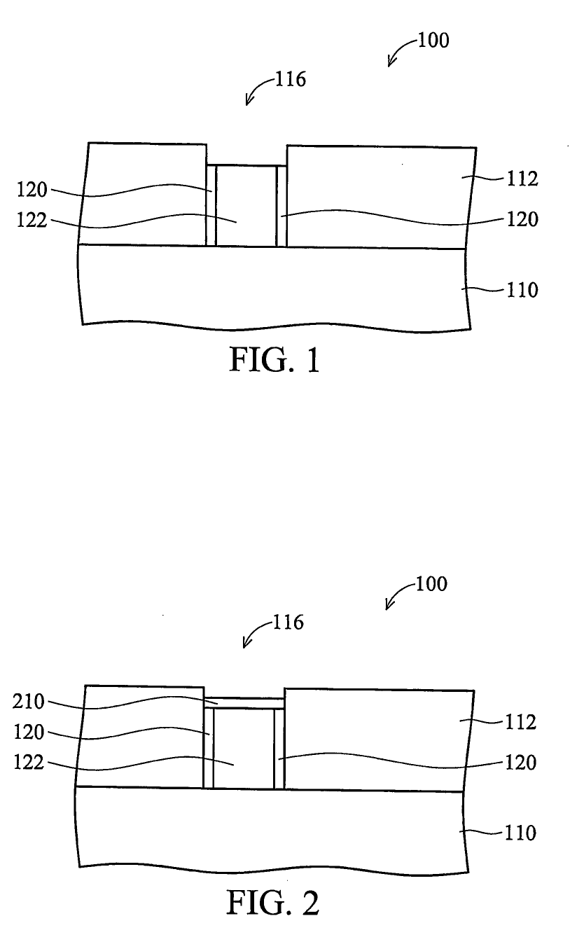

FIGS. 1-4 illustrate cross-section views of a first embodiment of the present invention in which a multi-layer passivation structure is formed on a metal layer. Referring first to FIG. 1, a workpiece 100 is provided. The workpiece 100 comprises a semiconductor substrate 110 having a first ILD layer 112 formed thereon. The semiconductor substrate 110 may comprise silicon or other semiconductor materials. The semiconductor substrate 110 may also include other active components or circuits (not shown). The workpiece 100 may include other conductive layers or other semiconductor elements, e.g. transistors, diodes, etc.

The first ILD layer 112 may comprise dielectric materials such as silicon oxide or dioxide, which has a dielectric constant of about 4.0. Alternatively, and more preferably, the first ILD layer 112 comprises low-K dielectric materials, such as materials having a dielectric constant (K) less than about 4.0 (or the dielectric constant of silicon dioxide), for example. The low-K material may comprise, for example, diamond-like carbon, fluorinated silicate glass or fluorinated silicon oxide glass (FSG), SiOₓC_{y}, Spin-On-Glass, Spin-On-Polymers, silicon carbon material, compounds thereof, composites thereof, and/or combinations thereof. The first ILD layer 112 may comprise a plurality of layers.

The first ILD layer 112 is preferably a low-K dielectric material formed by any suitable method known in the art. In an embodiment, the first ILD layer 112 comprises an oxide that may be formed by chemical vapor deposition (CVD) techniques using tetra-ethyl-ortho-silicate (TEOS) and oxygen as a precursor. The first ILD layer 112 is preferably about 200 Å to about 10,000 Å in thickness, but more preferably 2,000 Å. Other thicknesses and materials, such as silicon oxide, may be used.

An opening 116 is formed in the first ILD layer 112. The opening 116 may be a trench, via, or other pattern into which a conductive layer is to be formed. For example, in an embodiment, the opening 116 comprises a long thin trench that is relatively straight, or that curves and digresses in bends or other patterns to form conductive lines within a metal layer.

The opening 116 may be formed by photolithography techniques known in the art. Generally, photolithography techniques involve applying a photoresist material (not shown) and exposing the photoresist material in accordance with a desired pattern. The photoresist material is then developed to remove a portion of the photoresist material, thereby exposing the underlying material in accordance with the desired pattern. The remaining photoresist material protects the underlying material from subsequent processing steps, such as etching, performed to form the opening 116 in the first ILD layer 112. The etching process may be a wet or dry, anisotropic or isotropic, etch process, but preferably is an anisotropic dry etch process. After the opening 116 is formed in the first ILD layer 112, the remaining photoresist, if any, may be removed. Other processes, such as electron beam lithography (EBL) or the like, may be utilized to form the opening 116.

It should be noted that the process discussed above described a single-damascene process for illustrative purposes only. Other processes, such as a dual-damascene process may be utilized in accordance with an embodiment of the present invention. For example, a dual-damascene process may be utilized to form a trench and a via through one or more layers of the first ILD layer 114.

After the opening 116 is formed, a first barrier layer 120 a and conductive layer 122 are formed in the opening. The first barrier layer 120 may be formed of one or more adhesion layers and/or barrier layers. In an embodiment, the first barrier layer 120 is formed of one or more layers of conductive materials, such as titanium, titanium nitride, tantalum, tantalum nitride, or the like. In an exemplary embodiment, the first barrier layer 120 is formed of a thin layer of tantalum nitride and a thin layer of tantalum deposited by CVD techniques. In this embodiment, the combined thickness of the tantalum nitride and tantalum layers is about 5 Å to about 300 Å.

The opening 116 may be filled with the conductive material by, for example, performing a blanket deposition process to a thickness such that the opening 116 is at least substantially filled. The conductive layer 122 may comprise metals, elemental metals, transition metals, or the like. In an exemplary embodiment, the conductive layer 122 is copper. The conductive layer 122 may also be formed by depositing a seed layer and performing an electroplating process.

A planarization process, such as a chemical-mechanical process (CMP), may be performed to planarize the surface and to remove excess deposits of the material used to form the first barrier layer 120 and the conductive layer 122.

Furthermore, a preclean process may be performed to remove impurities along the surface of the conductive layer 122. The pre-clean process may be a reactive or a non-reactive pre-clean process. For example, a reactive process may include a plasma process using a hydrogen-containing plasma, and a non-reactive process may include a plasma process using an argon-containing or helium-containing plasma. The pre-clean process may be also a plasma process using a combination of the above gases.

It should be noted that FIG. 1 illustrates an optional embodiment in which the conductive layer 122 is recessed in the opening 116 from the surface of the first ILD layer 112. The recess may be formed during the pre-clean process or by a separate process step. In other embodiments, however, the surface of the conductive layer 122 and the surface of the first ILD layer 112 may form a substantially planar surface.

FIG. 2 illustrates the workpiece 100 after a glue layer 210 has been formed in accordance with an embodiment of the present invention. Preferably, the material selected to form the glue layer 210 exhibits good adhesion properties with the underlying conductive layer 122. In the embodiment in which the conductive layer 122 is formed of copper or a copper compound, it has been found that a relatively pure (e.g., greater than or equal to about 95 atomic %) metal alloy of cobalt (Co), nickel (Ni), a combination thereof, or the like provides good adhesive qualities. The glue layer 210 may contain other elements, such as tungsten, phosphorous, molybdenum, rhenium, boron, combinations thereof, alloys thereof, or the like. The glue layer 210 may be formed by any suitable method, such as an electroless process, a self-assembling process, a selective chemical-vapor deposition process, or the like.

In a preferred embodiment, the glue layer 210 is formed by an electroless process and is preferably about 20 Å to about 200 Å in thickness. In an embodiment, a glue layer 210 comprising cobalt and phosphorous may be formed by an electroless process using a solution of cobalt salt, CoCl₂, CoSO₄, or the like using a reduction agent of NaH₂PO₂.2H₂O, a complex agent of Na₃C₆H₅O₇.2H2O with surface activation and a deposition temperature of 70-95° C.

In another embodiment, a glue layer 210 comprising cobalt and boron may be formed by an electroless process using a solution of cobalt salt, CoCl₂, CoSO₄, or the like using a reduction agent of NaBH₄, (CH₃)2NHBH₃, or the like, a complex agent of Na₃C₆H₅O₇.2H₂O at a deposition temperature of 70-95° C. In this embodiment, it is preferred that a stabilizer be used and optional surface activation may be used. Other materials and processes may be used.

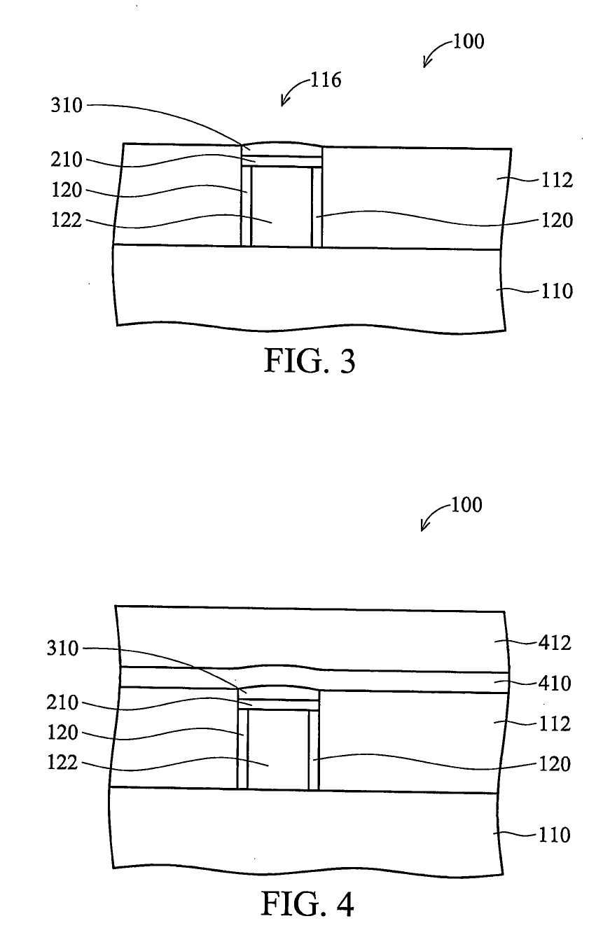

FIG. 3 illustrates the workpiece 100 after a passivation/barrier layer 310 has been formed in accordance with an embodiment of the present invention. Preferably, the material selected to form the passivation/barrier layer 310 exhibits good adhesion properties with the glue layer 210 and good barrier properties to prevent or reduce diffusion from the conductive material into the first ILD layer 112 or other materials. In the embodiment in which the conductive layer 122 is formed of copper or a copper compound and the glue layer 210 comprises Co and/or Ni, it has been found that a metal alloy of cobalt (Co), nickel (Ni), a combination thereof, or the like, less pure (e.g., less than or equal to about 95 atomic %) than the glue layer 210 provides good adhesive and barrier qualities. The passivation/barrier layer 310 may contain other elements, such as tungsten, phosphorous, molybdenum, rhenium, boron, combinations thereof, alloys thereof, or the like. The passivation/barrier layer 310 may be formed by any suitable method, such as an electroless process, a self-assembling process, a selective chemical-vapor deposition process, or the like.

In a preferred embodiment, the passivation/barrier layer 310 is formed by an electroless process and is about 20 Å to about 200 Å in thickness. In an embodiment, a passivation/barrier layer 310 comprising cobalt, phosphorous, and boron may be formed by an electroless process using a solution of cobalt salt, CoCl₂, CoSO₄, or the like using a reduction agent of NaH₂PO₂.2H₂O and NaBH₄, (CH₃)2NHBH₃, or the like, a complex agent of Na₃C₆H₅O₇.2H₂O at a deposition temperature of 70-95° C. In this embodiment, it is preferred that a stabilizer be used and optional surface activation may be used.

In another embodiment, a passivation/barrier layer 310 comprising cobalt, phosphorous, and tungsten may be formed by an electroless process using a solution of cobalt salt, CoCl₂, CoSO₄, or the like, and a solution of (NH₄)2WO₄, Na₂WO₄, H₃[P(W₃P₁₀)₄], or the like using a reduction agent of NaH₂PO₂.2H₂O, a complex agent of Na₃C₆H₅O₇.2H₂O, and a deposition temperature of 70-95° C.

In another embodiment, a passivation/barrier layer 310 comprising cobalt, tungsten, and boron may be formed by an electroless process using a solution of cobalt salt, CoCl₂, CoSO₄, or the like, and a solution of (NH₄)2WO₄, Na₂WO₄, H₃[P(W₃O₁₀)₄], or the like using a reduction agent of NaBH₄, (CH₃)2NHBH₃, or the like, a complex agent of Na₃C₆H₅O₇.2H₂O at a deposition temperature of 70-95° C. In this embodiment, it is preferred that a stabilizer be used and optional surface activation may be used.

In another embodiment, a passivation/barrier layer 310 comprising cobalt, molybdenum, and tungsten may be formed by an electroless process using a solution of cobalt salt, CoCl₂, CoSO₄, or the like, and a solution of (NH₄)2MoO₄, Na₂MoO₄, or the like using a reduction agent of NaH₂PO₂.2H₂O, a complex agent of Na₃C₆H₅O₇.2H₂O, and a deposition temperature of 70-95° C.

In another embodiment, a passivation/barrier layer 310 comprising cobalt, molybdenum, and boron may be formed by an electroless process using a solution of cobalt salt, CoCl₂, CoSO₄, or the like, and a solution of (NH₄)2MoO₄, Na₂MoO₄, or the like using a reduction agent of NaBH₄, (CH₃)2NHBH₃, or the like, a complex agent of Na₃C₆H₅O₇.2H₂O at a deposition temperature of 70-95° C. In this embodiment, it is preferred that a stabilizer be used and optional surface activation may be used.

Other processes and materials may be used. In particular, the glue and passivation/barrier layers may be formed of a material comprising nickel.

FIG. 4 illustrates the workpiece 100 after an optional etch stop layer 410 and a second ILD layer 412 have been formed thereon in accordance with an embodiment of the present invention. The etch stop layer 410 may be formed on the surface of the first ILD layer 112, and the second ILD layer 412 may be formed on the etch stop layer 410. It should be noted that a planarization step, which may be performed by a chemical-mechanical polishing (CMP) process, may be performed prior to the formation of the etch stop layer 410. The etch stop layer 410 may be formed of any material that provides a high-etch selectivity between the etch stop layer 410 and the subsequently-formed second ILD layer 412.

The second ILD layer 412 is preferably formed of a low-K dielectric material, such as fluorosilicate glass (FSG) or the like. In an exemplary embodiment, the second ILD layer 412 is formed of FSG, and the etch stop layer 410 is formed of SiN, SiC, a low-k dielectric film, or the like. A SiN layer may be formed, for example, by plasma-enhanced chemical-vapor deposition (PECVD) techniques, and the FSG layer may be formed by PECVD. Preferably, the etch stop layer 410 is about 50 Å to about 1000 Å in thickness, and the second ILD layer 412 is about 200 Å to about 10,000 Å in thickness, but more preferably about 2000 Å.

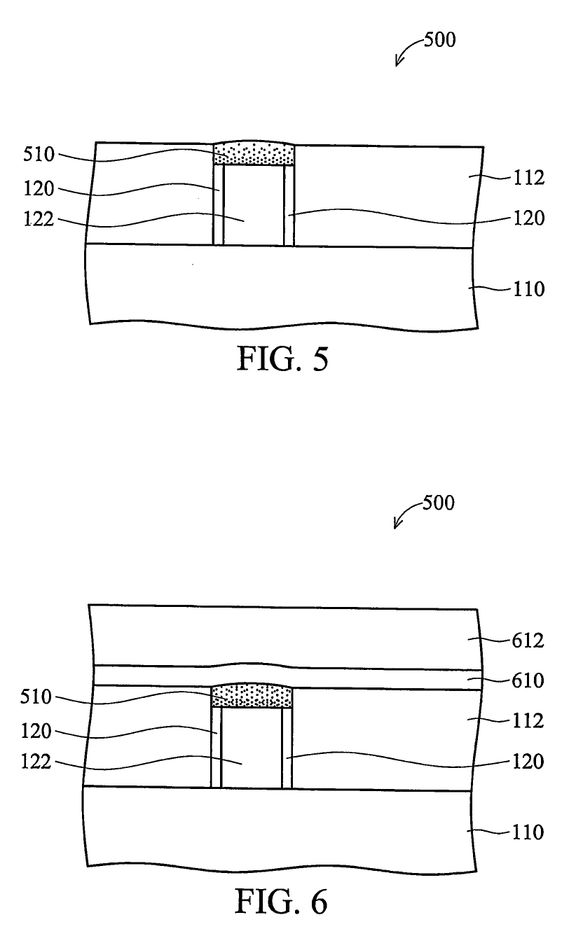

FIGS. 5-6 illustrate cross-section views of a second embodiment of the present invention in which a gradient cap layer is formed on a metal layer. The process illustrated in FIGS. 5-6 assume a workpiece 500 formed in a manner similar to workpiece 100 illustrated in FIG. 1, wherein like numerals refer to like elements formed as described above with reference to FIG. 1.

Referring now to FIG. 5, a gradient cap layer 510 has been formed on the conductive layer 122. The gradient cap layer 510 is preferably formed of a metal alloy having a higher purity level near the conductive layer 122 than near the surface. It has been found that a gradient cap layer 510 having these characteristics promotes greater adhesive properties to the conductive layer 122 and greater barrier properties to prevent or reduce diffusion. In an embodiment of the present invention in which the conductive layer 122 is copper or a copper alloy, it has been found that a gradient layer having a relatively pure (greater than or equal to about 95 atomic %) cobalt and/or nickel content near the conductive layer 122 and a less pure (less than or equal to about 95 atomic %) cobalt and/or nickel content near the surface of the gradient cap layer 510 provides a cap layer having good adhesive and barrier layer properties.

In this embodiment, the gradient cap layer 510 may be formed by an electroless process and is preferably about 50 Å to about 200 Å in thickness. In an embodiment, a gradient cap layer 510 comprising cobalt and phosphorous may be formed by an electroless process using a solution of cobalt salt, CoCl₂, CoSO₄, or the like using a reduction agent of NaH₂PO₂.2H₂O, a complex agent of Na₃C₆H₅O₇.2H2O with surface activation and a deposition temperature of 70-95° C. The gradient concentration of phosphorous may be generated by altering the flow rate of the phosphorous during the deposition process.

In another embodiment, a gradient cap layer 510 comprising cobalt and boron may be formed by an electroless process using a solution of cobalt salt, CoCl₂, CoSO₄, or the like using a reduction agent of NaBH₄, (CH₃)2NHBH₃, or the like, a complex agent of Na₃C₆H₅O₇.2H₂O at a deposition temperature of 70-95° C. In this embodiment, it is preferred that a stabilizer be used and optional surface activation may be used. Other materials and processes may be used. The gradient concentration of boron may be generated by altering the flow rate of the phosphorous during the deposition process.

FIG. 6 illustrates the workpiece 500 of FIG. 5 after an optional etch stop layer 610 and second ILD layer 612 have been formed. The etch stop layer 610 and second ILD layer 612 may be formed as described above with reference to the etch stop layer 410 and the second etch stop layer 412 of FIG. 4.

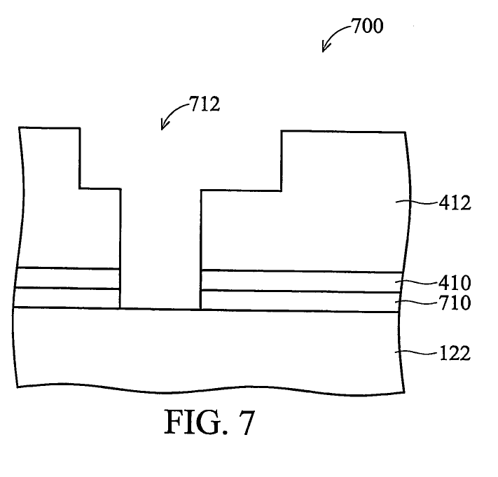

FIG. 7 illustrates a workpiece 700 that illustrates a connection to an interconnect formed in accordance with an embodiment of the present invention. It should be noted that FIG. 7 is drawn from perspective corresponding to a plane orthogonal to the plane of FIG. 4 or 6 and intersecting the conductive layer 122. Accordingly, elements in FIG. 7 having like reference numerals as elements in FIGS. 4 and 6 refer to like elements. It should be noted that cap layer 710 refers to the gradient cap layer 510 of FIG. 5 or the glue layer 210 and the passivation/barrier layer 310 of FIG. 4.

As illustrated in FIG. 7, an opening 712 is formed through the second ILD layer 412 to provide electrical contact to the underlying conductive layer 122. The opening 712 may be formed by standard (single or dual) damascene processes known in the art. It should be noted that the opening is formed through the etch stop layer 410 as well as the cap layer 710. It has been found that removing the cap layer 710 within the opening 712 provides a better electrical connection to the underlying conductive layer 122 characterized by less resistance.

In a preferred embodiment, the cap layer 710 is substantially removed. In alternative embodiments, however, portions of the cap layer 710 may remain. For example, in an embodiment in which the cap layer 710 corresponds to the glue layer 210 and the passivation/barrier layer 310 of FIG. 4, the passivation/barrier layer 310 may be substantially or completely removed and at least a portion of the glue layer 210 may remain. As another example, in an embodiment in which the cap layer 710 corresponds to the gradient cap layer 510 of FIG. 5, at least a portion of the gradient cap layer 510 may remain.

Although the present invention and its advantages have been described in detail, it should be understood that various changes, substitutions and alterations can be made herein without departing from the spirit and scope of the invention as defined by the appended claims. For example, different types of materials and processes may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit comprising:
a conductive layer in a trench of a first dielectric layer; and
a gradient cap layer on the conductive layer.

2. The integrated circuit of claim 1, wherein the conductive layer comprises copper.

3. The integrated circuit of claim 1, wherein the conductive layer is recessed from a surface of the first dielectric layer.

4. The integrated circuit of claim 1, wherein the gradient cap layer comprises cobalt, nickel, or combinations thereof.

5. The integrated circuit of claim 1, wherein the gradient cap layer comprises a metal alloy that is greater than or equal to about 95% (atomic percent) cobalt, nickel, or combinations thereof near the conductive layer.

6. The integrated circuit of claim 1, wherein the gradient cap layer comprises a metal alloy that is less than or equal to about 95% (atomic percent) cobalt, nickel, or combinations thereof in an area opposite from the conductive layer.

7. The integrated circuit of claim 1, wherein the gradient cap layer comprises a metal alloy that includes cobalt, nickel, tungsten, phosphorous, molybdenum, rhenium, boron, or combinations thereof.

8. The integrated circuit of claim 1, further comprising:
a second dielectric layer over the first dielectric layer; and
an opening in the second dielectric layer, wherein the opening extends through at least a portion of the gradient cap layer.

9. The integrated circuit of claim 8, wherein the gradient cap layer is completely removed within the opening.

10. An integrated circuit comprising:
a conductive layer in a trench of a first dielectric layer;
a first cap layer on the conductive layer, the first cap layer comprising a metal alloy that is greater than or equal to about 95% (atomic percent) cobalt, nickel, or combinations thereof; and
a second cap layer on the first cap layer, the second cap layer comprising a metal alloy that is less than or equal to about 95% (atomic percent) cobalt, nickel, or combinations thereof.

11. The integrated circuit of claim 10, wherein the conductive layer is recessed from a surface of the first dielectric layer.

12. The integrated circuit of claim 10, wherein the first cap layer comprises a metal alloy that includes cobalt, nickel, tungsten, phosphorous, molybdenum, rhenium, boron, or combinations thereof.

13. The integrated circuit of claim 10, wherein the second cap layer comprises a metal alloy that includes tungsten, phosphorous, molybdenum, rhenium, boron, or combinations thereof.

14. The integrated circuit of claim 10, further comprising:
a second dielectric layer over the conductive layer and the first dielectric layer; and
an opening in the second dielectric layer, wherein the opening extends through the second cap layer.

15. The integrated circuit of claim 14, wherein the opening extends through the first cap layer.

16. An integrated circuit comprising:
a conductive layer in a trench of a first dielectric layer; and
a gradient cap layer on the conductive layer, wherein the gradient cap layer comprises a metal alloy that is greater than or equal to about 95% (atomic percent) cobalt, nickel, or combinations thereof near the conductive layer and less than or equal to about 95% (atomic percent) cobalt, nickel, or combinations thereof in an area opposite from the conductive layer.

17. The integrated circuit of claim 16, wherein the conductive layer comprises copper.

18. The integrated circuit of claim 16, wherein the conductive layer is recessed from a surface of the first dielectric layer.

19. The integrated circuit of claim 16, wherein the gradient cap layer comprises cobalt, nickel, or combinations thereof.

20. The integrated circuit of claim 16, wherein the gradient cap layer comprises a metal alloy that includes tungsten, phosphorous, molybdenum, rhenium, boron, or combinations thereof.

21. The integrated circuit of claim 16, further comprising:
a second dielectric layer over the first dielectric layer; and
an opening in the second dielectric layer, wherein the opening extends through at least a portion of the gradient cap layer.

22. The integrated circuit of claim 21, wherein the gradient cap layer is completely removed within the opening.
